(19) United States
(12) Patent Application Publication
(10) Pub. No.: US 2017/0134854 A1
(43) Pub. Date: May 11, 2017

(54) MULTI-RATE FILTER SYSTEM

(71) Applicant: CIRRUS LOGIC INTERNATIONAL SEMICONDUCTOR LTD., EDINBURGH (GB)

(72) Inventors: Erik Lindahl, Stockholm (SE); Ludvig Lindblom, Linköping (SE); Pär Gunnars Risberg, Solna (SE); Landy Toth, Doylestown, PA (US)

(21) Appl. No.: 15/411,466

(22) Filed: Jan. 20, 2017

Related U.S. Application Data
(62) Division of application No. 14/371,020, filed on Jul. 8, 2014.
(60) Provisional application No. 61/584,855, filed on Jan. 10, 2012.
(60) Provisional application No. 61/658,560, filed on Jun. 12, 2012.

(51) Int. Cl. H04R 3/04; H03H 17/02

(52) U.S. Cl. CPC H04R 3/04; H03H 17/0261; H03H 17/0294; H04R 2430/03

(57) ABSTRACT

A multi-rate filter system is disclosed. More particularly, a computationally efficient multi-rate filter system for processing an audio stream on a consumer electronics device is disclosed. The multi-rate filter system includes a plurality of multi-rate filtering blocks, at least one block including a linear filter component. At least one multi-rate filtering block may include a nonlinear signal processing component. The multi-rate filter system may include a nonlinear functional block. A method of filtering a signal is also disclosed.

### CROSS-REFERENCE TO RELATED APPLICATIONS

The present application is a divisional application of U.S. patent application Ser. No. 14/371,020, filed Jun. 8, 2014, a national stage application which claims the benefit of and priority to PCT International Application No. PCT/US2013/020740, filed Jan. 9, 2013, which claims the benefit of and priority to U.S. Provisional Application No. 61/584,855, filed Jan. 10, 2012, and U.S. Provisional Application No. 61/658,560, filed Jun. 12, 2012, the entire contents of each of which are hereby incorporated by reference in their entirety.

### BACKGROUND

Technical Field

The present disclosure is directed to digital filters and particularly to multi-rate digital filters for audio signal processing.

Background

Mobile technologies and consumer electronic devices (CED) continue to expand in use and scope throughout the world. In parallel with continued proliferation, there is rapid technical advance of device hardware and components, leading to increased computing capability and incorporation of new peripherals onboard a device along with reductions in device size, power consumption, etc.

Many CEDs rely on signal processing with digital filters to perform a wide range of functions on the device (e.g. audio/video signal processing, sensor signal processing, voice recognition, etc.).

A feed forward or a feedback digital filter typically includes a number of equally spaced taps with each tap separated by a delay line and multiplied by a filter coefficient. The filter coefficients determine the impulse response of the filter.

A feed forward digital filter for use on a signal with broad spectral content (e.g. a signal with several orders of magnitude of bandwidth), may often require excessive sampling of the signal, particularly as related to the low frequency content thereof. In addition, the resulting complexity of the filter may be challenging to implement in resource constrained devices, as it may consume additional hardware and software resources with increased bandwidth coverage and complexity.

As the size and complexity of the filter are increased to accommodate additional signal spectrum, it becomes more challenging to tune the filter coefficients to produce the desired frequency response. In addition, applying adaptive, learning and/or optimization algorithms to the real-time adjustment of filter coefficients is much more challenging to implement as the size and complexity of the digital filter is increased.

### SUMMARY

One objective of the present disclosure is to provide a filter system.

Another objective is to provide a filter system for enhancing audio output from a consumer electronics device.

The above objectives are wholly or partially met by devices, systems, and methods described herein. In particular, features and aspects of the present disclosure are set forth in the appended claims, following description, and the annexed drawings.

According to a first aspect there is provided, a multi-rate filter system including an input channel configured to receive an input signal, an output channel configured to output a filtered signal, a cascade of multi-rate filter blocks coupled between the input channel and the output channel. At least one of the multi-rate filter blocks includes a bandselector comprising a bandselector input, a highpass bandselector output, a lowpass bandselector output connected to a subsequent multi-rate filter block, and a downsampler connected between the bandselector input and the lowpass bandselector output, a signal processing block coupled to the highpass bandselector output, the signal processing block comprising a linear filter component, and a bandcombiner connected to the signal processing block, the bandcombiner comprising two bandcombiner inputs, a bandcombiner output, and an upsampler, the first bandcombiner input connected to the signal processing block, the second bandcombiner input connected to a subsequent multi-rate filter block, and the bandcombiner output connected to a prior multi-rate filter block, the upsampler connected between the bandcombiner inputs and the bandcombiner output.

In aspects, the linear filter component may be selected from a group including a finite impulse response (FIR) filter, an infinite impulse response (IIR) filter, a Kalman filter, a neural network, a fuzzy logic filter, a lattice wave filter, a linear phase filter, a near linear phase filter, and combinations thereof. The linear filter component may include reconfigurable filter parameters in accordance with the present disclosure.

In aspects, the signal processing block may include a nonlinear filter component in accordance with the present disclosure connected to the linear filter component. Some non-limiting examples of a suitable nonlinear filter component include a compressor, a polynomial, a limiter, and combinations thereof.

In aspects, one or more multi-rate filter blocks may include an observer in accordance with the present disclosure configured to output an observer signal, the observer connected to the signal processing block between the highpass bandselector output and the first bandcombiner input. The observer may include a power monitor. One or more filter components (e.g the nonlinear filter component, the linear filter component) may be configured to respond to the observer signal (e.g. by changing a filter gain, alter a parameter, attack, release, etc.).

In aspects, the multi-rate filter system may include a nonlinear functional block (NLFB) including an NLFB input and an NLFB output. The NLFB input may be connected to the bandcombiner output of a first multi-rate filter block and the NLFB output may be connected to the bandcombiner input of a second second multi-rate filter block. The nonlinear function block may include a psychoacoustic function.

In aspects, the downsampler may be an m:1 downsampler, where m is a sample rate, and the upsampler may be a 1: k upsampler, where k is a sample rate. The sample rates m and k may be equal. The sample rates m and/or k may be less than or equal to 2, less than or equal to 1.5, less than or equal to 1.33, or less than or equal to 1.25.

In aspects, the multi-rate filter blocks may span an audio signal bandwidth.

In aspects, the bandselector may include a low pass filter connected between the bandselector input and the bandselector lowpass output, and a high pass filter connected between the bandselector input and the bandselector highpass output. A complimentary filter pair may be formed by the low pass filter and high pass filter.

In aspects, the bandcombiner may include a summer connected to the bandcombiner inputs and the upsampler and/or a low pass filter connected between the upsampler and the bandcombiner output.

In aspects, the multi-rate filter system may include a control channel configured to receive a control signal, with at least one multi-rate filter block being connected to the control channel.

In aspects, the linear filter component and/or the nonlinear filter component may be configured to respond to the control signal.

According to another aspect there is provided, use of a multi-rate filter system in accordance with the present disclosure, in a consumer electronics device.

According to yet another aspect there is provided, use of a multi-rate filter system in accordance with the present disclosure, to process an audio signal.

According to aspects there is provided, a method for filtering a signal, the method including, processing an input signal with a plurality of multi-rate filter blocks, the processing of at least one multi-rate filter block including, downsampling to produce a downsampled signal, providing the downsampled signal to a subsequent multi-rate filter block, processing with a linear filter component to form a linear filtered signal, processing with a nonlinear filter component to form a nonlinear filtered signal, combining or selecting the linear filtered signal and/or the nonlinear filtered signal to form a filtered output signal, and upsampling the filtered output signal to form an increased rate signal.

In aspects, the method may include processing at least one increased rate signal with a nonlinear functional block (NLFB) to form a nonlinear processed signal, providing the nonlinear processed signal to a prior multi-rate filter block, and/or providing the increased rate signal to a prior multi-rate filter block.

Some suitable non-limiting examples of the linear filter component include a finite impulse response (FIR) filter, an infinite impulse response (IIR) filter, a Kalman filter, a neural network, a fuzzy logic filter, and combinations thereof.

Suitable non-limiting examples of the nonlinear filter component include a compressor, a polynomial, a limiter, and combination thereof.

According to aspects there is provided a method for matching a multi-rate filter system in accordance with the present disclosure to a predetermined wideband filter, the method including, assigning the number of multi-rate filter blocks in the multi-rate filter system, calculating an initial guess for one or more of the multi-rate filter blocks, optimizing the multi-rate filter blocks towards the wideband filter to form one or more updated multi-rate filter blocks; and constructing a matched multi-rate filter system from the updated multi-rate filter blocks.

The step of calculating may be performed via any method in accordance with the present disclosure. In one aspect, the step of calculating may be performed using a Parks-McClellan algorithm.

The step of optimizing may be performed on one or more bandselectors and one or more bandcombiners included in the multi-rate filter system, and separately on one or more of the signal processing blocks included in the multi-rate filter system.

The method may include adding a nonlinear function block to one or more of the multi-rate filter blocks and optionally configuring the nonlinear function block to match a psychoacoustic function, a compressor, a limiter, or the like.

### BRIEF DESCRIPTION OF THE DRAWINGS

FIG. 1 shows a schematic of a multi-rate filter system in accordance with the present disclosure.

FIGS. 2a-e show diagrams of processing blocks associated with a multi-rate filter system in accordance with the present disclosure.

FIG. 3 shows a nonlinear functional block for implementing an audio enhancement algorithm with a multi-rate filter system in accordance with the present disclosure.

FIG. 4 shows a feedback system for use with a multi-rate filter system in accordance with the present disclosure.

FIG. 5 shows an example of a multi-rate filter system including a nonlinear functional block in accordance with the present disclosure.

FIGS. 6a-b show examples of frequency bands associated with a multi-rate filter system in accordance with the present disclosure.

FIGS. 7a-b show a method for optimizing a multi-rate filter in accordance with the present disclosure and a resulting error spectral response.

### DETAILED DESCRIPTION

Particular embodiments of the present disclosure are described hereinbelow with reference to the accompanying drawings; however, the disclosed embodiments are merely examples of the disclosure and may be embodied in various forms. Well-known functions or constructions are not described in detail to avoid obscuring the present disclosure in unnecessary detail. Therefore, specific structural and functional details disclosed herein are not to be interpreted as limiting, but merely as a basis for the claims and as a representative basis for teaching one skilled in the art to variously employ the present disclosure in virtually any appropriately detailed structure. Like reference numerals may refer to similar or identical elements throughout the description of the figures.

By consumer electronic device is meant a cellular phone (e.g. a smartphone), a tablet computer, a laptop computer, a portable media player, a television, a portable gaming device, a gaming console, a gaming controller, a remote control, an appliance (e.g. a toaster, a refrigerator, a bread maker, a microwave, a vacuum cleaner, etc.) a power tool (a drill, a blender, etc.), a robot (e.g. an autonomous cleaning robot, a care giving robot, etc.), a toy (e.g. a doll, a figurine, a construction set, a tractor, etc.), a greeting card, a home entertainment system, an active loudspeaker, a sound bar, etc.

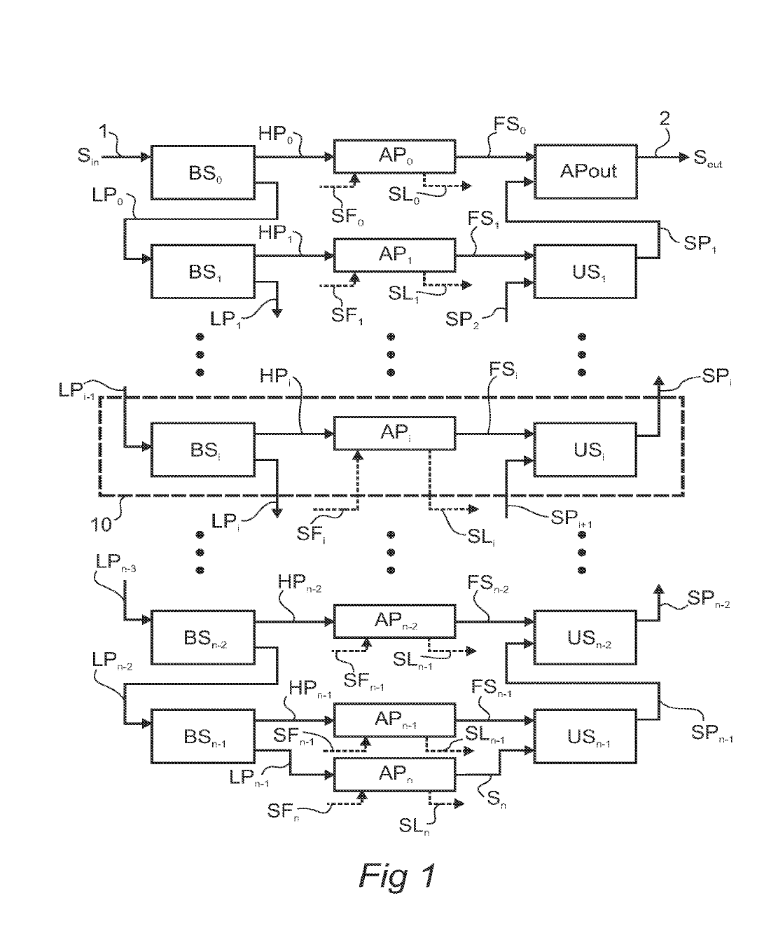

FIG. 1 shows a multi-rate filter system in accordance with the present disclosure. The filter system includes an input channel 1 configured to accept an input signal Sᵢₙ from an external source (e.g. a processor, an signal streaming device, an audio feedback device, a wireless transceiver, an ADC, an audio decoder circuit, a DSP, etc.), and an output channel 2 for outputting a filtered signal Sₒᵤₜ, and a plurality of multi-rate filter blocks 10.

At least one of the multi-rate filter blocks 10 includes a bandselector BS, configured to accept a signal from the input channel 1 or a previous multi-rate filter block 10 and to produce a highpass bandselector output signal HPᵢ, and a lowpass bandselector output signal LPᵢ to be delivered to a subsequent multi-rate filter block or to a subband processing block (e.g. a signal processing block covering the lowest signal band of interest). The multi-rate filter block 10 may also include a signal processing block APᵢ connected to the bandselector BSᵢ. The signal processing block APᵢ may include a linear filter component (e.g. a finite impulse response (FIR) filter, an infinite impulse response (IIR) filter, a Kalman filter, a neural network, a fuzzy logic filter, a butterworth filter, a lattice wave filter, etc.). The multi-rate filter block 10 may also include a bandcombiner connected to the signal processing block APᵢ. The bandcombiner USᵢ may include two bandcombiner inputs, a bandcombiner output, and an upsampler.

The first bandcombiner input FSᵢ may be connected to the signal processing block APᵢ, the second bandcombiner input SPᵢ₊₁ may be connected to a subsequent multi-rate filter block, and the bandcombiner output SPᵢ connected to a prior multi-rate filter block. The upsampler may be connected between the bandcombiner inputs FSᵢ, SPᵢ₊₁ and the bandcombiner output SPᵢ.

The bandselector BSᵢ may be configured to isolate a signal band to produce the bandselector highpass output HPᵢ. This function may be achieved with a high pass filter. The band selector may also be configured to produce a lowpass bandselector output LPᵢ at a resampled rate. This function may be achieved using a downsampler (e.g. an m:1 downsampler where m is a sample rate, a 8:1, 6:1, 4:1, 3:1, 2:1, 1.5:1, 1.25:1, downsampler, an adaptive sampling unit, an asynchronous sample rate converter, etc.), optionally in conjunction with a low pass filter. The highpass filter and the lowpass filter included in the bandselector BSᵢ may be complimentary filter pairs (i.e. so as to provide perfectly matched filters and to simplify the filter design). The downsampler associated with each bandselector BSᵢ may be configured to perform a different change in sampling rate, from the other downsamplers in the system, it may be similar, etc. (i.e. each downsampler may have a unique value m, m may be the same for a plurality or all of the downsamplers, etc.).

Each signal processing block APᵢ may be configured so as to operate at an associated sample rate. The sample rate may be determined by the associated downsampler or a filter block controller (not explicitly shown). A filter block controller may be configured to set filter parameters for each of the components of the filter system upon startup, upon firmware update, etc. Each signal processing block APᵢ may be configured to process the associated highpass bandselector output signal HPᵢ with a predetermined degree of precision (i.e. bit count). In one non-limiting example, signal processing blocks APᵢ associated with progressively lower frequency bands, may be configured to analyze the associated signals with increasing degree of precision. The associated downsampler may be configured to increase the precision of the output generated therefrom by an amount related to the downsampling parameter. Such changes in precision may be advantageous to compromise between delay and the number of filter blocks 10 in the filter system.

In aspects, the signal processing block APᵢ may include a linear filter component (e.g. a finite impulse response (FIR) filter, an infinite impulse response (IIR) filter, a Kalman filter, a neural network, a fuzzy logic filter, a butterworth filter, etc.), for modifying the signal content in the selected band. In aspects, the signal processing block APi may include a nonlinear filter component nLBᵢ (a clipper, a compressor, a limiter, an integrator, a multiplier, a convolution, a rectifier, a piecewise linear shaping function, a nonlinear transfer function, and/or an asymmetric polynomial function to calculate at least a portion of the second enhanced signal, etc.). The linear and/or nonlinear filter components may be configured to process the signal content within the selected band. The nonlinear filter may be configured to generate signal content out of band. The acceptable out of band range may be determined by the bandwidth associated with the band and the sample rate associated with the band.

In aspects, the bandcombiner USᵢ may be connected to the signal processing block APᵢ and the bandcombiner output SP₁₊₁ from a subsequent multi-rate filter block. The bandcombiner USᵢ may include a summer to combine the inputs signals thereto, an upsampler (e.g. an 1:k upsampler where k is a sample rate, a 1:1, 1:1.5, 1:1.2, 1:8, 1:6, 1:4 upsampler, an adaptive sampling unit, an asynchronous sample rate converter, etc.), to upsample the combined signals to form the bandcombiner output signal SPᵢ. In aspects, the bandcombiner USi may include a low pass filter connected to the upsampler, to prevent imaging of the bandcombiner output signal SPᵢ.

The band limits and the sample rates associated with each multi-rate filter block may be configured based upon the desired processing characteristics thereof. In a non-limiting example, wherein the multi-rate filter block 10 includes only linear signal processing components, the sample rate need only be 2× the associated upper limit of the associated band. Additional headroom may be provided by adjusting the cutoff frequency of the low pass filter in the associated bandselector BSᵢ. In a non-limiting example where the multi-rate filter block 10 includes nonlinear processing element, the ratio of the sample rate to the upper limit of the associated band may be greater than 2×, may be adaptively changed during processing, etc. In aspects, the multi-rate filter block 10 may include a look ahead buffer suitable for predicting changes in the signal and adaptively compensating the gain of a nonlinear filter block (e.g. attack and release of a compressor, a limiter, etc.), altering the relationships between the upper limit of the associated band and the sample rate, combinations thereof, or the like.

In aspects, the downsample rates m and the upsample rates k of the multi-rate filter blocks 10 may be equal to each other. In a non-limiting example, the downsample and upsample rates are equal to 2 (e.g. thus segmenting the signal spectrum into octave bands).

In aspects, the multi-rate filter may include an output stage (e.g. just prior to the output channel 2, connected to the output channel 2, included in the bandcombiner US₀). In aspects, the output stage may include an audio amplifier (e.g. a class AB, class D amplifier, etc.), a crossover (e.g. a digital cross over, an active cross over, a passive crossover, etc.), and/or an audio enhancement system (AES) including a psychoacoustic function each in accordance with the present disclosure.

In aspects, the multi-rate filter system or portion thereof (e.g. a component, a down-sampler, an up-sampler, a processing block, etc.), may be configured with an overall signal delay (i.e. the delay between the input signal 1 and the output signal 2). In aspects, the multi-rate filter system may be configured to provide an overall linear phase relationship between the input signal 1 and the output signal 2. As such, the multi-rate filter system may include one or more linear phase filters to provide the associated relationship. The multi-rate filter system may include one or more near linear phase filters, configured in order to provide a nearly linear phase relationship between the input thereto and the output therefrom. In aspects, the multi-rate filter system may be configured with a maximal delay below a predetermined value (e.g. less than 45 ms, less than 22 ms, less than 10 ms, etc.).

In aspects, the multi-rate filter may be included in a consumer electronics device. The multi-rate filter may be configured to compensate for one or more acoustic characteristics of the consumer electronics device. Some non-limiting examples of acoustic characteristics which may be compensated for by the multi-rate filter factors such as the loudspeaker design (speaker size, internal speaker elements, material selection, placement, mounting, covers, available back volume, etc.), device form factor, internal component placement, screen real-estate and material makeup, case material selection, hardware layout, and assembly considerations amongst others.

In aspects, the multi-rate filter system may be configured to compensate for one or more properties of a sound producing device such a film speaker. Some non-limiting examples of speaker properties to be compensated for include nonlinear transduction effects, memory effects, rate dependent hysteresis, mode breakup, large signal nonlinearities, limited bass response, environmental dependence (e.g. temperature, humidity, pressure differences, etc.), combinations thereof, and the like.

In aspects, the signal processing block APᵢ may include such functionality as FIR filtering, IIR filtering, warped FIR filtering, transducer artifact removal, disturbance rejection, user specific acoustic enhancements, user safety functions, emotive algorithms, psychoacoustic enhancement, signal shaping, single or multi-band compression, expanders or limiters, watermark superposition, spectral contrast enhancement, spectral widening, frequency masking, quantization noise removal, power supply rejection, crossovers, equalization, amplification, driver range extenders, power optimization, linear or non-linear feedback or feed-forward control systems, and the like. The signal processing block APᵢ may include one or more of the above functions, either independently or in combination. One or more of the included functions may be configured to depend on one or more pre-configurable and/or reconfigurable parameters. The functions may be combined to form an equivalent linear filter component and nonlinear filter component.

In aspects, the multi-rate filter system (e.g. via the collective combination of the signal processing blocks APₒ to APₙ) may be configured to provide echo cancellation, environmental artifact correction, reverb reduction, beam forming, auto calibration, stereo widening, virtual surround sound, virtual center speaker, virtual sub-woofer (by digital bass enhancement techniques), noise suppression, sound effects, or the like. One or more of the included functions may be configured to depend on one or more of the parameters.

In aspects, the multi-rate filter system (e.g. via the collective combination of the signal processing blocks APₒ to APₙ) may be configured to impose ambient sound effects onto an audio signal, such as by transforming an audio input signal conveyed via the input channel 1 with an ambient environmental characteristic (e.g. adjusting reverb, echo, etc.) and/or superimposing ambient sound effects onto the audio input signal akin to an environmental setting (e.g. a live event, an outdoor setting, a concert hall, a church, a club, a jungle, a shopping mall, a conference setting, an elevator, a conflict zone, an airplane cockpit, a department store radio network, etc.).

In aspects, the ambient sound effects may be configured so as to include specific information about a user, such as name, preferences, etc. The ambient sound effects may be used to securely superimpose personalized information (e.g. greetings, product specific information, directions, watermarks, handshakes, etc.) into an audio stream.

In aspects wherein the signal processing blocks APᵢ include associated linear filter components, the linear filter component may be optimized to enhanced the audio performance of a consumer electronics device into which it is implemented. A non-limiting example of a method for enhancing audio performance of a consumer electronic device (CED) includes placing the consumer electronic device including an audio signal source, one or more transducers, an integrated loudspeaker assembly, and a multi-rate filter system in accordance with the present disclosure into an acoustic test chamber with a plurality of audio sensors (e.g. microphones) spatially and optionally strategically arranged within the acoustic test chamber and/or on or within the CED (e.g. a microphone on a handset CED). A range of test audio signals (e.g. impulse signals, frequency sweeps, music clips, pseudo-random data streams, etc.) may be played on the consumer electronic device and monitored with the audio sensors. In an initial test, the multi-rate filter system may be substantially configured with one or more pass band linear filters (a null state whereby the multi-rate filter system is configured so as to not substantially affect the audio signal pathway through the CED).

In aspects, the signal processing block APᵢ transfer functions may be parametrically configured to compensate for the acoustic signature of the CED. One, non-limiting approach for calculating the transfer function(s) from the acoustic signature of the CED is to implement a time domain inverse finite impulse response (FIR) filter based upon the estimated acoustic signature of the CED. This may be implemented by performing one or more convolutions of the transfer functions with the acoustic responses of the CED to the audio input signals. An averaging algorithm may be used to optimize the transfer function(s) from the outputs measured across multiple sources and/or multiple test audio signals.

In one non-limiting example, the compensation transfer function may be calculated from a least squares (LS) time-domain filter design approach. If c(n) is the system response to be corrected (such as the output of an impulse response test) and a compensating filter is denoted as h(n), then one can construct C, the convolution matrix of c(n), as outlined in equation 1:

$$C = [ \begin{matrix}c ( 0 ) & & 0 \\ ⋮ & ⋱ & ⋮ \\ c ( {N}_{c} - 1 ) & ⋱ & c ( 0 ) \\ ⋮ & ⋱ & ⋮ \\ 0 & & c ( {N}_{c} - 1 )\end{matrix} ] \qquad [ equation 1 ]$$

where N_{c} is the length of the response c(n). C has a number of columns equal to the length of h(n) with which the response is being convoluted. Assuming the sequence h. has length denoted by Nₕ then the number of rows of C is equal to (Nₕ+N_{c}−1). Then, using a deterministic least squares (LS) approach to compare against a desired response, (in a non-limiting example, defined as the Kronecker delta function δ(n−m)), one can express the LS optimal inverse filter as outlined in equation 2:

h(n)=(C^{T}C)⁻¹C^{T}αₘ [equation 2]

where αₘ (n) is a column vector of zeroes with 1 in the mth position to create the modeling delay. The compensation filter h(n) can then be computed from equation 2 using a range of computational methods.

In aspects, the parametrically configurable transfer function(s) may be iteratively determined by subsequently running test audio signals on the CED with the updated transfer function(s) and monitoring the modified acoustic signature of the CED with the audio sensors. A least squares optimization algorithm may be implemented to iteratively update the transfer function(s) between test regiments until an optimal modified acoustic signature of the CED is obtained. Other, non-limiting examples of optimization techniques include non-linear least squares, L2 norm, averaged one-dependence estimators (AODE), Kalman filters, Markov models, back propagation artificial neural networks, Baysian networks, basis functions, support vector machines, k-nearest neighbors algorithms, case-based reasoning, decision trees, Gaussian process regression, information fuzzy networks, regression analysis, self-organizing maps, logistic regression, fractional derivative based optimization, time series models such as autoregression models, moving average models, autoregressive integrated moving average models, classification and regression trees, multivariate adaptive regression splines, and the like.

Due to the spatial nature of the acoustic signature of a CED, the optimization process may be configured so as to minimize error between an ideal system response and the actual system response as measured at several locations within the sound field of the CED. The multi-channel data obtained via the audio sensors may be analyzed using sensor fusion approaches. In many practical cases, the usage case of the CED may be reasonably well defined (e.g. the location of the user with respect to the device, the placement of the device in an environment, etc.) and thus a suitable spatial weighting scheme can be devised in order to prioritize the audio response of the CED in certain regions of the sound field that correspond to the desired usage case. In one, non-limiting example, the acoustic response within the forward facing visual range of a laptop screen may be favored over the acoustic response as measured behind the laptop screen during such tests. In this way, a more optimal multi-rate filter system may be formulated to suit a particular usage case for the CED.

In aspects, a method for optimizing a multi-rate filter system in accordance with the present disclosure may include optimizing the HDL implementation for reduced power, reduced footprint, or for integration into a particular semiconductor manufacturing process (e.g. 13 nm-0.5 μm CMOS, CMOS-Opto, HV-CMOS, SiGe BiCMOS, etc.). This may be advantageous for providing an enhanced audio experience for a consumer electronic device without significantly impacting power consumption or adding significant hardware or cost to an already constrained device.

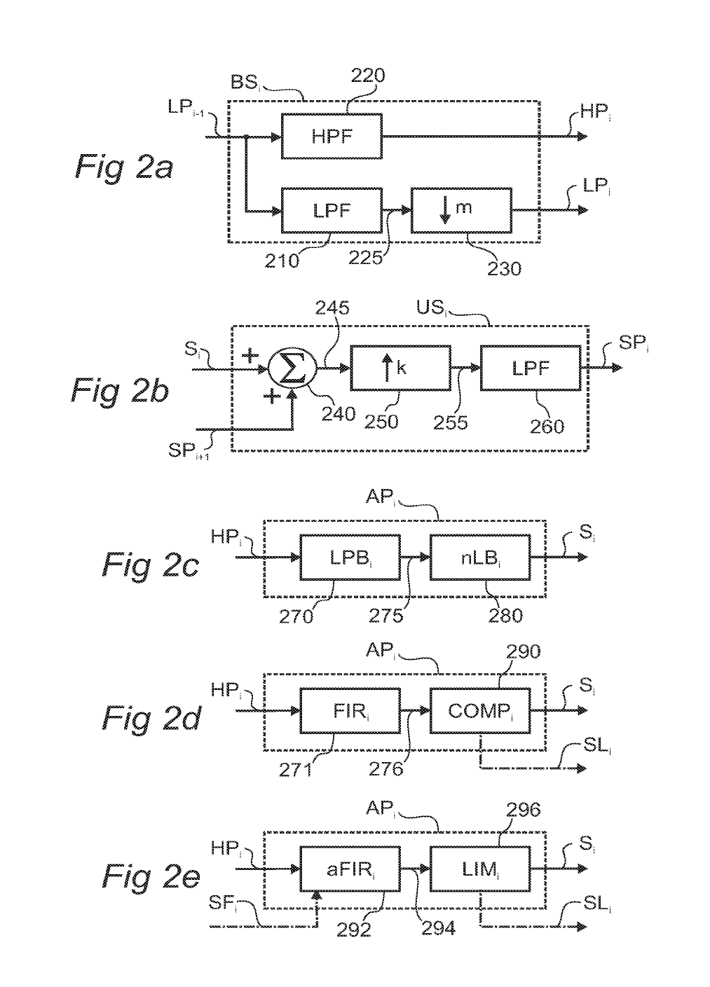

FIG. 2a shows a bandselector BSᵢ in accordance with the present disclosure. The bandselector BSᵢ includes a bandselector input LPᵢ₋₁, a highpass bandselector output HPᵢ,and a lowpass bandselector output LPᵢ. The bandselector BSᵢ includes a high pass filter 220 connected between the bandselector input LPᵢ₋₁ and the highpass bandselector output HPᵢ. The bandselector BSᵢ also includes a low pass filter 210 connected to the bandselector input LPᵢ₋₁ and an intermediate filtered signal 225. The bandselector BSᵢ also includes a downsampler 230 connected to the intermediate filtered signal 225 and the lowpass bandselector output LPᵢ. The low pass and high pass filters may be selected as known to one skilled in the art. The architecture herein may be advantageous in providing a simple structure to provide the low pass and high pass filters as a complimentary digital filter pair.

In aspects, one or more of the low pass and/or high pass filters may be configured with linear phase characteristics (e.g. as linear phase FIR filters, etc.). In aspects, one or more of the low pass and/or high pass filters may be configured with near linear phase characteristics (i.e. with phase characteristics that deviate from a linear phase characteristic by less than a predetermined limit). Such configurations may be advantageous to manage and/or reduce the overall phase distortion introduced to the signal path by the multi-rate filter system during use (e.g. as may be introduced during reconstruction of the individual bands during formation of the output signal). Near linear phase filter characteristics may be advantageous for managing the relationship between the overall phase distortion and the delay associated with the multi-rate filter system.

FIG. 2b shows a bandcombiner USᵢ in accordance with the present disclosure. The bandcombiner USᵢ includes two bandcombiner inputs Sᵢ, SPᵢ₊₁ and a bandcombiner output SPᵢ. The bandcombiner USᵢ includes a summer connected to the bandcombiner inputs Sᵢ, SPᵢ₊₁ and an intermediate combined signal 245. The bandcombiner USi further includes an upsampler 250 connected to the intermediate combined signal 245 to produce an upsampled intermediate signal 255. The bandcombiner USᵢ includes a low pass filter 260 connected to the upsampled intermediate signal 255 and the bandcombiner output SPᵢ so as to ensure the output thereof is not aliased and/or imaged.

In aspects, the upsampler 250 may be configured with one or more interpolation filters so as to reduce imaging associated with the upsampled intermediate signal 255.

In aspects, the bandcombiner USᵢ may include one or more filter elements (i.e. the low pass filter 260, included in the upsampler 250, etc.) configured so as to manage, reduce, and/or minimize the delay introduced into the signal during use. Such filter elements may be configured as linear phase filters, near linear phase filters (e.g. a filter prescribed wherein the filter phase variation is within a predetermined tolerance of a linear phase variation), or the like. Such filters may be optimized during an optimization method in accordance with the present disclosure.

FIG. 2c shows an example of a signal processing block APᵢ in accordance with the present disclosure. The signal processing block APᵢ is connected to an associated highpass bandselector output HPᵢ and a first bandcombiner input Sᵢ. The signal processing block APᵢ includes a linear filter component 270 and a nonlinear filter component 280 both in accordance with the present disclosure. The linear filter component 270 and the nonlinear filter component 280 are shown connected in series by a linear filtered signal 255. The nonlinear filter component 280 is configured to produce a nonlinear filtered signal (e.g. in this case the first bandcombiner input Sᵢ). Other interconnections of the filter components may be used in practice (serial connections, parallel connections, functionally equivalent merging of components, etc.). In aspects, one or more of the filters 270, 280 may include a delay function and/or a phase compensation function.

FIG. 2d shows an alternative example of a signal processing block APᵢ in accordance with the present disclosure. The signal processing block APᵢ is connected to an associated highpass bandselector output HPᵢ and a first bandcombiner input Sᵢ. The signal processing block APᵢ includes a finite impulse response (FIR) filter 271 connected in series with a compressor 290 both in accordance with the present disclosure. The finite impulse response (FIR) filter 271 is configured to output a linear filtered signal 276. The compressor 290 is configured to accept the linear filtered signal 276 and output a nonlinear filtered signal (e.g. in this case the first bandcombiner input Sᵢ). One or more of the filters 271, 290 may include a delay function and/or a phase compensation function.

In aspects, the compressor 290 may include an observer. The observer may be configured to monitor at least one signal within the signal processing block APᵢ (e.g. the linear filtered signal 276, the first bandcombiner input Sᵢ, an intermediate signal, a representation of such signals, etc.). In aspects, the observer may be configured to calculate a strength signal.

In aspects, the strength signal may be evaluated simply as being equal to a band-passed input signal. Some other non-limiting examples for calculating a strength signal from an associated input signal (or filtered version thereof) include, a power signal, instantaneous power signal, averaged power signal, frequency band averaged signal, peak signal, an envelope, a filtered envelope, a Kalman-filtered power estimation technique, noise power spectral density, loudspeaker excursion estimators, an autocorrelation parameter, combinations thereof, or the like.

In aspects, the compressor (e.g. or equivalently a nonlinear filter component) may be configured to respond to the observer output (e.g. an observer signal SLᵢ). The observer may be configured to output an observer signal SLᵢ for use by another component and/or block in the multi-rate filter system.

FIG. 2e shows an alternative example of a signal processing block APᵢ in accordance with the present disclosure. The signal processing block APᵢ is connected to an associated highpass bandselector output HPᵢ and a first bandcombiner input Sᵢ. The signal processing block APᵢ includes an adaptive finite impulse response (aFIR) filter 292 connected to a feedback signal channel SFᵢ and connected in series with a compressor 296 (in this case a limiter) both in accordance with the present disclosure. The adaptive finite impulse response (FIR) filter 292 is configured to output a linear filtered signal 294. The limiter 296 is configured to accept the linear filtered signal 294 and output a nonlinear filtered signal (e.g. in this case the first bandcombiner input Sᵢ).

In general the adaptation process associated with the adaptive finite impulse response (aFIR) filter 292 may be configured so as to be sufficiently slow to maintain an essentially linear behavior from the aFIR filter 292 over the signal bandwidth of interest (e.g. the audio frequency band).

In aspects, the limiter 296 may include an observer in accordance with the present disclosure. The observer may be configured to monitor at least one signal within the signal processing block APi (e.g. the linear filtered signal 294, the first bandcombiner input Si, an intermediate signal, a representation of such signals, etc.). The observer may be configured to calculate a strength signal in accordance with the present disclosure.

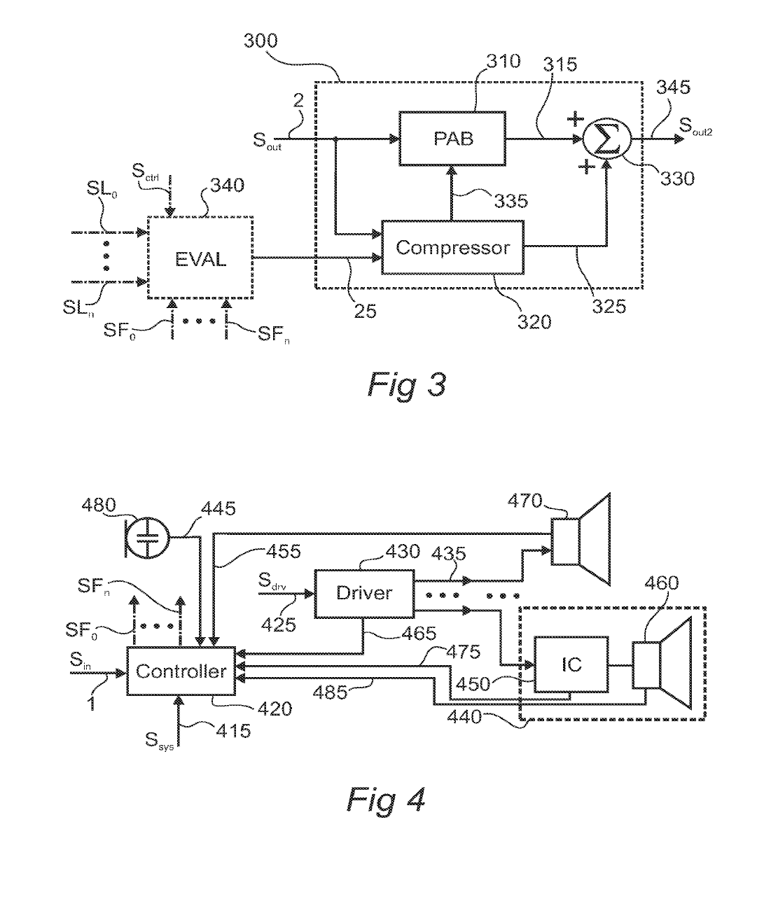

FIG. 3 shows a nonlinear functional block 300 for implementing an audio enhancement algorithm in combination with a multi-rate filter system in accordance with the present disclosure. In the non-limiting example shown, the nonlinear functional block 300 shows an illustrative example of a bass enhancement system 300 in accordance with the present disclosure. The bass enhancement system 300 may be configured to accept an input signal, Sₒᵤₜ 2 from the multi-rate filter system and a control signal 25 from an evaluation block 340, to produce an enhanced output signal, Sₒᵤₜ₂ 345. The evaluation block 340 may be configured to accept an external control signal S_{ctrl}, one or more feedback signals SFₒ to SFₙ, and one or more observer signals SLₒ to SLₙ. The evaluation block 340 may combine signals operably generated by many multi-rate filter blocks 10 to form a collective strength signal, power level, etc. to optionally direct the bass enhancement system 300.

In aspects, the bass enhancement system 300 may include a psychoacoustic bass enhancement block (PAB) 310 and a compressor 320. The compressor 320 may be configured to accept the input signal 2 or a related signal thereof (e.g. filtered, resampled, clipped, input signal 2, etc.), and the control signal 25, and to produce a first enhanced signal 325 and an internal control signal 335. The PAB 310 may be configured to accept the input signal 2 or a related signal therefrom (e.g. filtered, resampled, clipped, input signal 2, etc.) and the internal control signal 335, and to produce a second enhanced signal 315. In aspects, the first enhanced signal 325 and the second enhanced signal 315 may be combined (e.g. added, mixed, etc.) in a combination block 330 to produce the enhanced output signal, Sₒᵤₜ₂ 345.

The system 300, the PAB 330 and/or the compressor 320 may include one more filters (e.g band pass filters, low pass filters, high pass filters, adaptable filters, polyphase FIR filters, FIR filters, lattice wave filters, etc.) for isolating one or more frequency bands (e.g. band-1, band-2, band-3, band-m, band-n signals, etc.) from the input signal 2 for further analysis and/or enhancement. In aspects, the compressor 320 may include a filter for isolating a portion of the input signal content residing roughly within the bass audio range (e.g. 10-80 Hz, 30-60 Hz, 35-50 Hz, 100-300 Hz, 120-250 Hz, etc.). The compressor 320 may be configured to adjust the bandwidth limits of the filter in real-time (e.g. as directed by the external control signal S_{ctr1}). Alternatively, additionally, or in combination the multi-rate filter system may be tapped at one or more bandcombiner outputs SPᵢ in order to retrieve one or more band limited signals for use in the nonlinear functional block (e.g. the bass enhancement system 300).

FIG. 4 shows an illustrative example of a feedback system including a controller 420 and some illustrative feedback mechanisms in accordance with the present disclosure. The controller 420 may be configured to generate one or more feedback signals SFₒ to SFₙ (equivalently considered external control signals). The control signals maybe used by various blocks in multi-rate filter system to control gain adjustments, adapt filter parameters, and the like. The controller 420 may be connected to the input channel 1 so as to accept the input signal Sᵢₙ to contribute to the generation of the feedback signals SFₒ to SFₙ. In aspects, the controller 420 may be configured to accept the input signal 1 and to generate one or more feedback signals SFₒ to SFₙ with an entirely feed forward signal path. The controller 420 may be configured to accept a system control signal S_{sys} 415 so as to adjust one or more control signals.

In aspects, the system control signal 415 may be a power management signal, a volume scale, a power setting (e.g. ultra-low power, low power, full power, etc.), a signal related to trade-off between audio quality and power, a user input signal, or the like.

When implemented into an audio processing system, the audio processing system may include a driver 430. The driver 430 may be driven by an audio processing output signal 425, at least partially dependent on the output signal Sₒᵤₜ and/or the enhanced signal 355. The driver 430 may generate one or more output signals 435 for driving one or more loudspeakers 460, 470, loudspeaker driver modules 440, and/or integrated circuits 450 included therein. The controller 420 may be configured to accept one or more sensor signals 445, 455, 465, 475, 485 from one or more audio components within a complete audio signal processing system. Some non-limiting examples include current, voltage, and/or temperature sensor signal 465 from the driver 430, a current, voltage, displacement, temperature, and/or acceleration sensor signal 455, 485 from one or more of the loudspeakers 460, 470, and a current, voltage, impedance, temperature, limiter, and/or envelop sensor signal 475 from one or more integrated circuits 450 included in the audio processing system.

In aspects, the controller 420 may be configured to accept an audio sensor signal 445 as operably produced by one or more microphones 480 included in the audio processing system. The controller 420 may be configure to accept a sensor signal (not explicitly shown) from one or more accelerometers, gyroscopes, GPS sensors, temperature sensors, humidity sensors, battery life sensors, current sensors, magnetic field sensors, or the like.

In aspects, a range of feedback algorithms may be implemented in the controller 420 to relate the sensor signals 445, 455, 465, 475, 485 to the feedback signals SFₒ to SFₙ. Some non-limiting examples of feedback algorithms include speaker/drive temperature overload feedback, negative feedback based on one or more aspects of the audio sensor signal 445 (e.g. an amplitude based feedback, a distortion based feedback, etc.), a distortion limiting algorithm (e.g. via measurement of the audio sensor signal 445), combinations thereof, and the like.

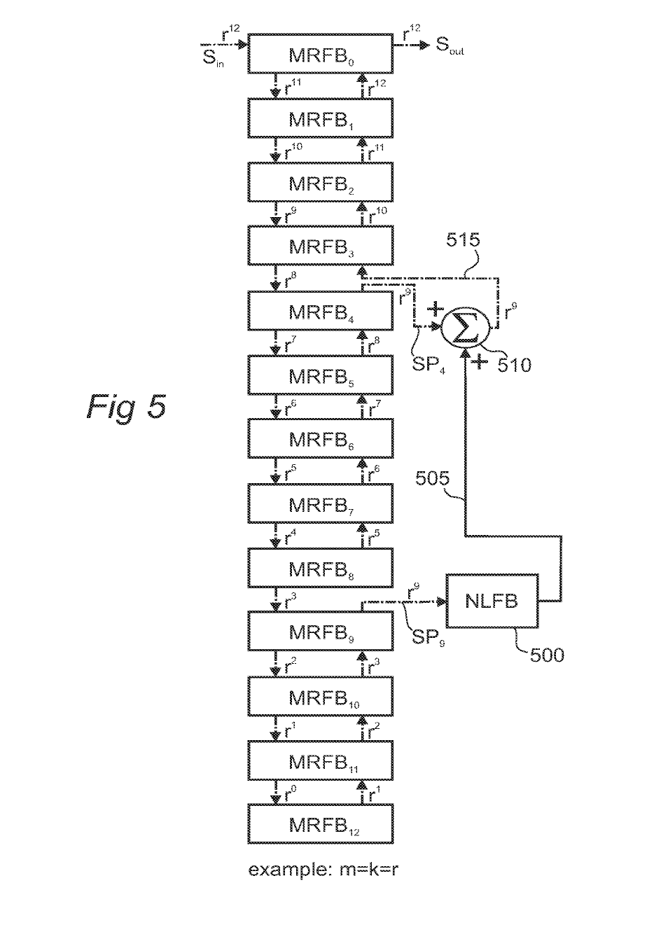

FIG. 5 shows a non-limiting example of a multi-rate filter system including a nonlinear functional block in accordance with the present disclosure. The multi-rate filter system includes a plurality of multi-rate filter blocks MRFB₀ to MRFB₁₂ each in accordance with the present disclosure. The multi-rate filter block MRFB₀ is connected to an input channel 1, configured so as to accept an input signal Sᵢₙ, and is connected to an output channel 2, configured so as to output a filtered signal Sₒᵤₜ.The downsampler and upsampler in each multi-rate filter block MRFBᵢ are configured with sampling ratios equal to “r”. Such a limitation is only for illustration purposes. The sampling ratios may be configured to any values and need not be equal to each other.

In aspects, the maximum frequency associated with each signal within the multi-rate filter system is indicated as a power of r (e.g. rⁿ). Thus the bands associated with this multi-rate filter are logarithmically spaced across the signal spectrum. Such limitation is shown only for illustrative purposes. The sampling ratios may be configured to any unique values and need not be equal to each other.

In aspects, the multi-rate filter system may include a nonlinear functional block 500 in accordance with the present disclosure. The nonlinear functional block 500 is connected to the bandcombiner output SP₉ of the multi-rate filter block MRFB₉. In the example shown, the bandcombiner output is oversampled (i.e in this case to a value corresponding to the upper band limit of r⁹). Thus there is sufficient headroom in SP₉ to accommodate at least a portion of the distortion introduced by the nonlinear functional block 500. The nonlinear functional block 500 is connected to a summer 510. The summer 510 may be connected to the bandcombiner output SP₄ of the multi-rate filter block MRFB₄. In this non-limiting example, the sample rates of the summer 510 inputs are equivalent. The summer output 515 is connected to the prior multi-rate filter block MRFB₃ so as to add the nonlinear functional block 500 enhanced signal back into the multi-rate filter block cascade.

In aspects, the nonlinear functional block 500 may be a bass enhancement block 300 in accordance with the present disclosure. The nonlinear functional block 500 may also be equivalent to any nonlinear filter component in accordance with the present disclosure.

The structure shown may be advantageous for effectively coupling highly nonlinear functions into the cascade structure of the multi-rate filter system.

In aspects, the multi-rate filter block cascade may be tapped at any bandcombiner output SPᵢ. Such taps may be used to construct wider band signals from the individual band signal of the multi-rate filter cascade.

In aspects, the sample rates of at least one downsampler and/or upsampler in the multi-rate filter system may be adaptively configurable. At least one downsampler and/or upsampler sample rate may be configured so as to coincide with an acoustic feature (e.g. an acoustic resonance, a bass band transition, a jitter, etc.) of an associated consumer electronics device into which the multi-rate filter system is included.

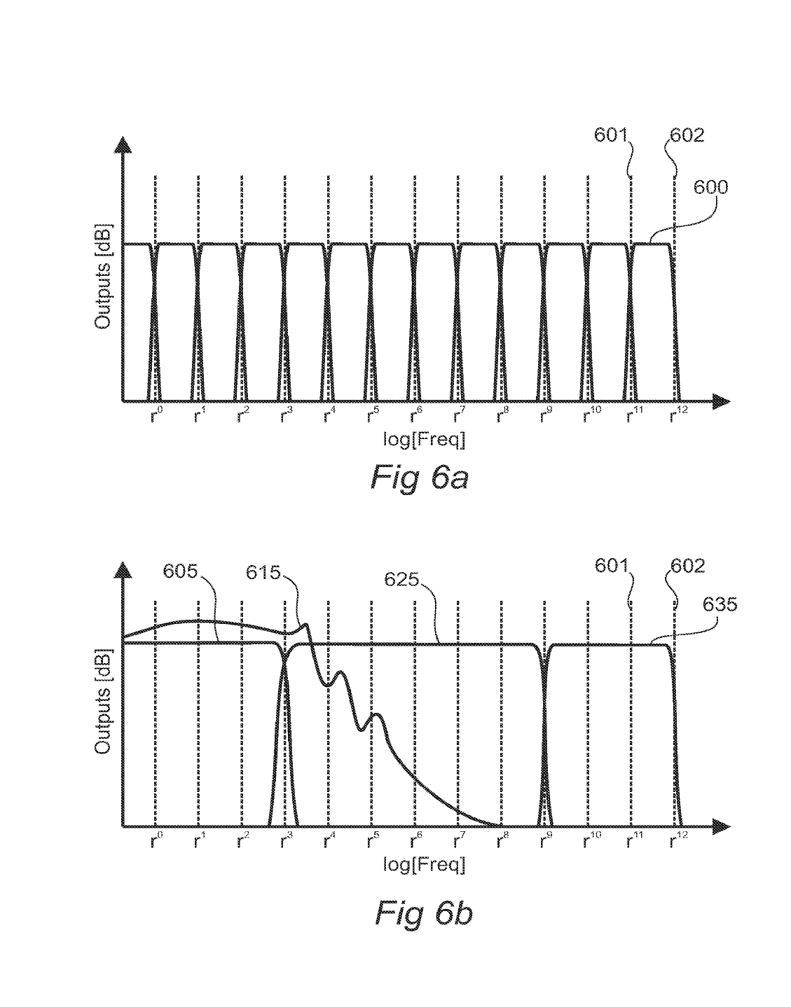

FIG. 6a-b show examples of the frequency spectrum associated with the example multi-rate filter system shown in FIG. 5. FIG. 6a shows a log-log relationship between frequency and frequency content of a signal 600 associated with each multi-rate filter block 10 of this specific example. The signal 600 is bound by an upper limit frequency 602 and a lower limit frequency 601. As shown, the bands are logarithmically spaced in frequency. Such a limitation is only shown for illustration purposes and in aspects, the bands may be arbitrarily assigned. The sampling ratios may be configured to any values and need not be equal to each other. In aspects, the bands may be linearly spaced across the signal spectrum, nonlinearly spaced, logarithmically spaced, randomly spaced, etc.

FIG. 6b shows further examples of signal content associated with the example of FIG. 5. FIG. 6b shows a bass band portion 605 of the overall signal, as tapped at SP₉ in the example. The bass band portion 605 is passed to the nonlinear functional block 500 to produce a nonlinear filtered portion 615. In the non-limiting example shown, the nonlinear filtered portion 615 contains significant distortion, thus introducing signal content with a considerably higher frequency than could be sampled from the r³ band. Thus, by upsampling the bandcombiner output SP₉ to r₉, the additional frequency content can be accommodated without aliasing. The signal portion between SP6 and SP4 is shown as a midband portion 625 and is added to with the nonlinear filtered portion 615 in the summer and returned to the cascade to be integrated and upsampled with content in the upper band portion 635 of the signal.

In aspects, the multi-rate filter system may be embedded in an application specific integrated circuit (ASIC) or be provided as a hardware descriptive language block (e.g. VHDL, Verilog, etc.) for integration into a system on chip (SoC), an application specific integrated circuit (ASIC), a field programmable gate array (FPGA), or a digital signal processor (DSP) integrated circuit.

In aspects, a multi-rate filter system in accordance with the present disclosure may be configured to substantially match a predetermined single rate wide band filter. The wide band filter may be configured to compensate for one or more rendering characteristics of an audio rendering device (e.g. a consumer electronics device, a media rendering network, etc.). In one non-limiting example, the multi-rate filter system may be configured with a series of bands to collectively span the wide band spectrum associated with the wide band filter. The multi-rate filter system may include N bands, the bands configured as follows: N-1 bands spaced so as to fill a high frequency portion of the wide band filter spectrum (i.e. configured so as to span from the upper limit of the spectrum, Fₘₐₓ, down to a low to mid band frequency Fₘ), and an additional low band spanning from a substantially lower limit of the spectrum Fₘᵢₙ, up to the low to mid band frequency Fₘ. Each of the bands (i.e. each of the N-1 bands, the low frequency band, etc.) may include a signal processing block APᵢ connected to a bandselector BSᵢ in accordance with the present disclosure. The N-1 bands may be spaced linearly, logarithmically, with individually configured bandwidth, etc. in accordance with the present disclosure. In aspects, the low band may be configured so as to cover a bass band of the spectrum (e.g. perhaps correlated with the bass band of the associated device, covering relevant spectrum less than 1000 Hz, less than 500 Hz, less than 300 Hz, less than 150 Hz, less than 120 Hz, less than 80 Hz, etc.).

In aspects, the N-1 bands may be logarithmically spaced in accordance with the present disclosure (i.e. each band covering 1:m spectrum wherein m is a real number, 1:2, 1:1.5, half octave bands, quarter octave bands, etc.).

One or more of the low pass filters in each band may be configured to reduce cross talk, aliasing, imaging, etc. associated with the adjacent band structures, downsampling, and upsampling aspects of the multi-rate filter system. In one non-lmiting example, one or more of the low pass filters may be formed from linear phase FIR filters. One or more of the low pass filters may be configured with cutoff characteristics suitably placed to reduce aliasing and/or imaging of the signals to be processed by the associated bandselector BSᵢ bandcombiner USᵢ, and/or signal processing block APᵢ. In aspects, related to the use of linear phase filters, bands associated with shorter paths may include a delay element so as to maintain an equal delay between all band signals in the multi-rate filter system.

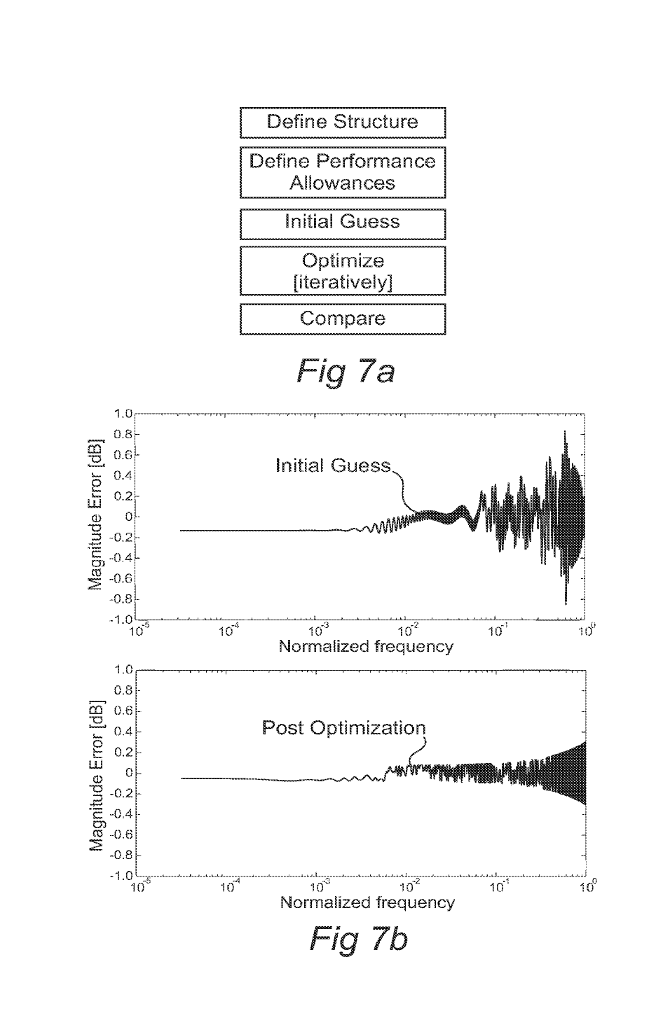

FIG. 7a-b show a method for optimizing a multi-rate filter to match a wide band target filter in accordance with the present disclosure and a resulting filter frequency response. FIG. 7a shows a method for optimizing a multi-rate filter system to match a wide band target filter in accordance with the present disclosure. The method includes defining the structure of the multi-rate filter system, defining the performance allowances (i.e. phase delay, phase distortion, and/or magnitude mismatch), providing an initial guess to match the target filter, optimizing the multi-rate filter system to match the target filter, comparing the optimized filter and the target in accordance with the performance allowances, and optionally iterating any of the above steps in order to satisfy the performance allowances.

In aspects, the step of optimizing may include optimizing the multi-rate filter system on the whole, in parts, or by fixing one or more portions of the system while optimizing one or more alternative aspects. The optimization procedure may be completed using one or more known techniques (e.g. nonlinear programming solvers, minimax constraint problem solvers, etc.). Other, non-limiting examples of optimization techniques include non-linear least squares, L2 norm, averaged one-dependence estimators (AODE), Kalman filters, Markov models, back propagation artificial neural networks, Baysian networks, basis functions, support vector machines, k-nearest neighbors algorithms, case-based reasoning, decision trees, Gaussian process regression, information fuzzy networks, regression analysis, self-organizing maps, logistic regression, fractional derivative based optimization, time series models such as autoregression models, moving average models, autoregressive integrated moving average models, classification and regression trees, multivariate adaptive regression splines, and the like.

In aspects, one or more of the filters in the multi-rate filter system may be optimized separately from each other. The filters in the bandselector BS, and the bandcombiner USᵢ may be designed (and optionally optimized) so as to define the band structures of the multi-rate filter to conform with the overall performance allowances of the filter. The bandselector BS, and the bandcombiner US, filters may be matched so as to provide the same values and/or reduce complexity of the filter system (i.e. perhaps so as to provide matching filter parameters, reduce memory requirements, etc.). The resulting bandselector BSᵢ and the bandcombiner USᵢ filters may then be held constant while the processing filters included in each of the signal processing blocks APᵢ are optimized in a secondary optimization procedure.

Additionally, alternatively, or in combination the filters in the multi-rate filter system may be collectively optimized with reference to the performance allowances. Such an approach may be advantageous for flexibly trading off between the performance allowances (i.e. may allow for more control over delay, phase distortion, and/or magnitude variation).

For purposes of demonstration, in one non-limiting example, the predetermined wide band filter may be a FIR filter with 2048 taps (e.g. a minimum phase FIR filter, linear phase FIR filter, etc.). The basic computational requirement for the wide band filter is 2048 computations per sample (i.e. 90MIPS at 44.1 kHz). An associated multi-rate filter may be provided with N bands (e.g. N=2, 3, 4, 5, 6, etc.) in accordance with the present disclosure. In one non-limiting example, the multi-rate filter may include logarithmically spaced bands (i.e. in a multi-rate filter with N=3, the bands may be approximately 22 kHz:44 kHz, 11 kHz:22 kHz, Fₘᵢₙ:11 kHz).

The multi-rate filter may be structured in accordance with the method described herein, and the performance allowances may be defined a priori. In one non-limiting example, the allowable delay is preferably less than or equal to 10 ms, the allowable phase distortion is zero (i.e. a linear phase configuration with associated delay elements in each band), and the allowable magnitude variation is set at less than or equal to 0.25 dB. For purposes of discussion, in this example, the delay allowance is relaxed while the linear phase aspect is enforced. Filters in the bandselector BSᵢ and the bandcombiner USᵢ are selected to have an order of 40. Initial guesses for the bandselector BSᵢ and the bandcombiner USᵢ filters were calculated using a Parks-McClellan algorithm and then optimized subject to weighted constraints relating to pass band flatness, stopband ripple, etc. of each of the filters.

Continuing with the example, processing filters associated with each signal processing block APᵢ are of order 64, except for the lowest band filter, which is arbitrarily provided with order 1024, 512, 256, 128, or 64 for N varying between N=2 and N=6. Initial guesses for the processing filters were made using a Parks-McClellan algorithm. The resulting optimized filters were then generated using an optimization technique in accordance with the present disclosure subject to constraints related to minimization of amplitude error under the constraints of minimum phase filter properties. Such a configuration may be advantageous for simplifying the overall optimization process.

In accordance with this example, the associated memory requirements, and computations requirements as a function of N are shown in Table 1:

TABLE 1

| | Memory Requirement | Computational Requirements |
|---|---|---|
| Order <N> | <words> | <MIPS> |
| wideband | 4096 | 90.3 |
| 2 | 2320 | 29.0 |
| 3 | 1606 | 15.3 |
| 4 | 1564 | 12.68 |
| 5 | 2098 | 12.43 |
| 6 | 3400 | 12.56 |

As can be seen from Table 1, the computational requirements for the multi-band filter system are considerably lower than those of the wideband filter for all N values studied. The memory requirements are also improved for a range of N (in this case for N values of 2 through 6).

FIG. 7b shows the error magnitude between the target wideband filter, the initial guess and for the post optimized multi-rate filter for the procedure described herein (shown in separate graphs). As can be seen in FIG. 7b, the magnitude error between the multi-rate filter and the target filter has been reduced by roughly a factor of 4 during the optimization procedure versus the initial guess.

In aspects, a multi-rate filter system in accordance with the present disclosure may be soft-coded into a processor, coded in VHDL, Verilog or other hardware descriptive language, flash, EEPROM, memory location, or the like. Such a configuration may be used to implement the multi-rate filter system in software, as a routine on a DSP, an FPGA, A CPLD, a processor, and ASIC, etc.

It will be appreciated that additional advantages and modifications will readily occur to those skilled in the art. Therefore, the disclosures presented herein and broader aspects thereof are not limited to the specific details and representative embodiments shown and described herein. Accordingly, many modifications, equivalents, and improvements may be included without departing from the spirit or scope of the general inventive concept as defined by the appended claims and their equivalents.

What is claimed is:

1. A multi-rate filter system comprising:
an input channel configured to receive an input signal;
an output channel configured to output a filtered signal; and
a cascade of multi-rate filter blocks coupled between the input channel and the output channel, at least one of the multi-rate filter blocks comprising:
a bandselector comprising a bandselector input, a highpass bandselector output, a lowpass bandselector output connected to a subsequent multi- rate filter block, and a downsampler connected between the bandselector input and the lowpass bandselector output;
a signal processing block coupled to the highpass bandselector output, the signal processing block comprising a linear filter component and a nonlinear filter component connected to the linear filter component; and
a bandcombiner connected to the signal processing block, the bandcombiner comprising two bandcombiner inputs, a bandcombiner output, and an upsampler, a first bandcombiner input connected to the signal processing block, a second bandcombiner input connected to a subsequent multi-rate filter block, and the bandcombiner output connected to a prior multi-rate filter block, the upsampler connected between the bandcombiner inputs and the bandcombiner output.

2. The multi-rate filter system in accordance with claim 1, wherein the nonlinear filter component has an input and an output, and the output is a nonlinear function of the input.

3. The multi-rate filter system in accordance with claim 1, wherein the nonlinear filter component comprises a compressor.

4. The multi-rate filter system in accordance with claim 1, wherein the nonlinear filter component comprises a limiter.

5. The multi-rate filter system in accordance with claim 1, wherein the nonlinear filter component comprises a clipper.

6. The multi-rate filter system in accordance with claim 1, wherein the nonlinear filter component comprises an integrator.

7. The multi-rate filter system in accordance with claim 1, wherein the nonlinear filter component comprises a multiplier.

8. The multi-rate filter system in accordance with claim 1, wherein the nonlinear filter component comprises a convolution.

9. The multi-rate filter system in accordance with claim 1, wherein the nonlinear filter component comprises a rectifier.

10. The multi-rate filter system in accordance with claim 1, wherein the nonlinear filter component comprises a piecewise linear shaping function.

11. The multi-rate filter system in accordance with claim 1, wherein the nonlinear filter component comprises a nonlinear transfer function.

12. The multi-rate filter system in accordance with claim 1, wherein the nonlinear filter component comprises an asymmetric polynomial function.

13. The multi-rate filter system in accordance with claim 1, wherein the nonlinear filter component is a combination comprising at least two of a clipper, a compressor, a limiter, an integrator, a multiplier, a convolution, a rectifier, a piecewise linear shaping function, a nonlinear transfer function, and an asymmetric polynomial function.

14. The multi-rate filter system in accordance with claim 1, wherein the linear filter component is selected from the group consisting of a finite impulse response (FIR) filter, an infinite impulse response (IIR) filter, a Kalman filter, a neural network, a fuzzy logic filter, and combinations thereof.

15. The multi-rate filter system in accordance with claim 14, wherein the linear filter component comprises reconfigurable filter parameters.

16. The multi-rate filter system in accordance with claim 1, wherein at least one multi-rate filter block comprises an observer configured to output an observer signal, the observer connected to the signal processing block between the highpass bandselector output and the first bandcombiner input.

17. The multi-rate filter system in accordance with claim 16, wherein the observer comprises a strength monitor.

18. The multi-rate filter system in accordance with claim 16, wherein the nonlinear filter component is configured to respond to the observer signal.

19. The multi-rate filter system in accordance with claim 17, wherein the observer is configured to calculate a strength signal from a signal within the signal processing block.

20. The multi-rate filter system in accordance with claim 19, wherein the strength signal is selected from the group consisting of a power signal, an instantaneous power signal, an averaged power signal, a frequency band averaged signal, a peak signal, an envelope, a filtered envelope, a Kalman-filtered power estimation, a noise power spectral density, a loudspeaker excursion estimation, an autocorrelation parameter, a band-passed input signal of the signal processing block, and combinations thereof.

21. The multi-rate filter system in accordance with claim 1, further comprising a nonlinear functional block (NLFB) including an NLFB input and an NLFB output, a first multi-rate filter block comprising a bandcombiner output, and a second multi-rate filter block comprising a bandcombiner input, the NLFB input connected to the bandcombiner output of the first multi-rate filter block, and the NLFB output connected to the bandcombiner input of the second multi-rate filter block.

22. The multi-rate filter system in accordance with claim 1, further comprising a control channel configured to receive a control signal, wherein at least one multi-rate filter block is connected to the control channel.

23. The multi-rate filter system in accordance with claim 22, wherein the linear filter component is configured to respond to the control signal.

24. The multi-rate filter system in accordance with claim 22, wherein the nonlinear filter component is configured to respond to the control signal.
